(19) United States
(12) Patent Application Publication
(10) Pub. No.: US 2025/0176180 A1
(43) Pub. Date: May 29, 2025

(54) SEMICONDUCTOR MEMORY DEVICE AND METHOD OF MANUFACTURING THE SAME

(71) Applicant: SK hynix Inc., Icheon-si Gyeonggi-do (KR)

(72) Inventors: Do Young KIM, Icheon-si Gyeonggi-do (KR); Eun Mee KWON, Icheon-si Gyeonggi-do (KR)

(73) Assignee: SK hynix Inc., Icheon-si Gyeonggi-do (KR)

(21) Appl. No.: 18/669,667

(22) Filed: May 21, 2024

(30) Foreign Application Priority Data
Nov. 28, 2023 (KR) 10-2023-0167749

(51) Int. Cl. H10B 43/27; G11C 16/04; H10B 41/10; H10B 41/27; H10B 43/10

(52) U.S. Cl. CPC H10B 43/27; G11C 16/0483; H10B 41/10; H10B 41/27; H10B 43/10

(57) ABSTRACT

Provided herein is a semiconductor memory device and a method of manufacturing the same. The semiconductor memory device includes a plurality of interlayer insulating structures, a plurality of conductive layers alternately stacked with the plurality of interlayer insulating structures, a plurality of data storage patterns spaced apart from each other in a direction in which the plurality of interlayer insulating structures and the plurality of conductive layers are alternately stacked, and a blocking insulating layer or blocking insulation pattern interposed between each data storage pattern and a corresponding conductive layer.

### CROSS-REFERENCE TO RELATED APPLICATION

The present application claims priority under 35 U.S.C. § 119(a) to Korean patent application number 10-2023-0167749 filed in the Korean Intellectual Property Office on Nov. 28, 2023, which application is incorporated herein by reference in its entirety.

### BACKGROUND

### 1. Technical Field

Various embodiments of the present disclosure generally relate to a semiconductor memory device and a method of manufacturing the semiconductor memory device, and more particularly to a three-dimensional (3D) semiconductor memory device and a method of manufacturing the 3D semiconductor memory device.

### 2. Related Art

A semiconductor memory device may be applied to a small electronic device as well as electronic systems in various fields, such as automobiles, medical fields, or data centers. Thus, there is a growing demand for the semiconductor memory device.

The semiconductor memory device may include a memory cell for storing data. A 3D semiconductor memory device includes memory cells arranged in three dimensions, the 3D semiconductor memory device being advantageous in achieving a large capacity compared to a 2D semiconductor memory device.

As the integration degree of memory cells in the 3D semiconductor memory device increases, a distance between the memory cells in the stacking direction of the memory cells decreases. Thus, the operational reliability of the semiconductor memory device may deteriorate.

### SUMMARY

An embodiment of the present disclosure may provide for a semiconductor memory device. The semiconductor memory device may include a channel layer extending in a first direction, a tunnel insulating layer extending along an outer wall of the channel layer in the first direction, a plurality of interlayer insulating structures arranged along an outer wall of the tunnel insulating layer, the plurality of interlayer insulating structures being spaced apart from each other in the first direction, a plurality of conductive layers alternately arranged with the plurality of interlayer insulating structures in the first direction, a plurality of data storage patterns interposed between the plurality of conductive layers and the tunnel insulating layer in a second direction, each of the plurality of data storage patterns being spaced apart from each other in the first direction, wherein the plurality of data storage patterns correspond to the plurality of conductive layers, respectively, and wherein the second direction is perpendicular to the first direction, a liner insulation pattern extending to cover a first surface of each of the plurality of data storage patterns facing the first direction, a second surface of each of the plurality of data storage patterns facing a direction opposite to the first surface, and a third surface of each of the plurality of data storage patterns facing the second direction, and a blocking insulating layer interposed between each of the plurality of conductive layers and the liner insulation pattern, wherein the liner insulation pattern includes a crystalline insulating layer.

An embodiment of the present disclosure may provide for a semiconductor memory device. The semiconductor memory device may include a channel layer extending in a first direction, a tunnel insulating layer extending along an outer wall of the channel layer in the first direction, a plurality of interlayer insulating structures arranged along an outer wall of the tunnel insulating layer, the plurality of interlayer insulating structures being spaced apart from each other in the first direction, a plurality of conductive layers alternately arranged with the plurality of interlayer insulating structures in the first direction, a plurality of data storage patterns interposed between the plurality of conductive layers and the tunnel insulating layer in a second direction, each of the plurality of data storage patterns being spaced apart from each other in the first direction, wherein the plurality of data storage patterns correspond to the plurality of conductive layers, respectively, and wherein the second direction is perpendicular to the first direction, a sacrificial insulation pattern covering a first surface of each of the plurality of data storage patterns facing the first direction, and a second surface of each of the plurality of data storage patterns facing a direction opposite to the first surface, and a blocking insulation pattern interposed between each of the plurality of data storage patterns and a corresponding conductive layer among the plurality of conductive layers. The blocking insulation pattern may be thicker than the sacrificial insulation pattern.

An embodiment of the present disclosure may provide for a method of manufacturing a semiconductor memory device. The method may include alternately stacking a plurality of first interlayer insulating layers and a plurality of sacrificial layers in a first direction, forming a hole that passes through the plurality of first interlayer insulating layers and the plurality of sacrificial layers, forming a plurality of second interlayer insulating layers on sidewalls of the plurality of first interlayer insulating layers facing the hole to define an uneven portion on a sidewall of the hole, forming a blocking insulating layer along the uneven portion to cover sidewalls of the plurality of second interlayer insulating layers and sidewalls of the plurality of sacrificial layers, forming a crystalline insulating layer on an inner wall of the blocking insulating layer to have a plurality of grooves corresponding to the plurality of sacrificial layers, forming a plurality of data storage patterns on an inner wall of the crystalline insulating layer to respectively fill the plurality of grooves of the crystalline insulating layer, etching a portion of the crystalline insulating layer exposed between the plurality of data storage patterns so that the crystalline insulating layer is separated into a plurality of liner insulation patterns, forming a tunnel insulating layer inside the hole to cover an area in which the crystalline insulating layer is etched and the plurality of data storage patterns, forming a channel layer along an inner wall of the tunnel insulating layer, and replacing the plurality of sacrificial layers with a plurality of conductive layers.

An embodiment of the present disclosure may provide for a method of manufacturing a semiconductor memory device. The method may include alternately stacking a plurality of first interlayer insulating layers and a plurality of sacrificial layers in a first direction, forming a hole that passes through the plurality of first interlayer insulating layers and the plurality of sacrificial layers, forming a plurality of second interlayer insulating layers on sidewalls of the plurality of first interlayer insulating layers facing the hole to define an uneven portion on a sidewall of the hole, forming a sacrificial insulating layer along the uneven portion to cover sidewalls of the plurality of second interlayer insulating layers and sidewalls of the plurality of sacrificial layers and to have a plurality of grooves corresponding to the plurality of sacrificial layers, forming a plurality of data storage patterns on an inner wall of the sacrificial insulating layer to respectively fill the plurality of grooves of the sacrificial insulating layer, forming a tunnel insulating layer inside the hole to cover the plurality of data storage patterns and the sacrificial insulating layer, forming a channel layer along an inner wall of the tunnel insulating layer, removing the plurality of sacrificial layers to define a plurality of openings that expose the sacrificial insulating layer, removing an exposed portion of the sacrificial insulating layer so that the plurality of data storage patterns are exposed through the plurality of openings, selectively depositing a preliminary layer on an exposed surface of each of the plurality of data storage patterns, forming a blocking insulation pattern by modifying the preliminary layer, and forming a plurality of conductive layers inside the plurality of openings that are opened by the blocking insulation pattern.

### BRIEF DESCRIPTION OF THE DRAWINGS

FIG. 1 is a circuit diagram illustrating a memory cell array of a semiconductor memory device according to an embodiment of the present disclosure.

FIGS. 2A and 2B are diagrams illustrating a semiconductor memory device according to embodiments of the present disclosure.

FIGS. 3A to 3D are sectional views illustrating a stacked structure of a plurality of memory cells according to embodiments of the present disclosure.

FIGS. 4A to 4H are sectional views illustrating a method of manufacturing a semiconductor memory device according to an embodiment of the present disclosure.

FIGS. 5A and 5B are sectional views illustrating a method of manufacturing a semiconductor memory device according to an embodiment of the present disclosure.

FIGS. 6A to 6I are sectional views illustrating a method of manufacturing a semiconductor memory device according to an embodiment of the present disclosure.

FIG. 7 is a sectional view illustrating a process of forming a preliminary layer according to an embodiment of the present disclosure.

FIGS. 8A to 8C are sectional views illustrating a method of manufacturing a semiconductor memory device according to an embodiment of the present disclosure.

FIG. 9 is a block diagram illustrating an electronic system according to an embodiment of the present disclosure.

### DETAILED DESCRIPTION

The specific structural and functional descriptions disclosed herein are merely illustrative for the purpose of describing embodiments according to the concept of the present disclosure. The embodiments according to the concept of the present disclosure can be modified in various forms and replaced with other equivalent embodiments. Thus, the present disclosure should not be construed as limited to the embodiments set forth herein.

It will be understood that, although the terms “first,” “second,” etc. may be used herein to describe various elements, these elements should not be limited by these terms. These terms are only used to distinguish one element from another element, and the order or number of components is not limited by the terms.

Various embodiments of the present disclosure are directed to a semiconductor memory device capable of improving operational reliability and a method of manufacturing the semiconductor memory device capable of improving operational reliability.

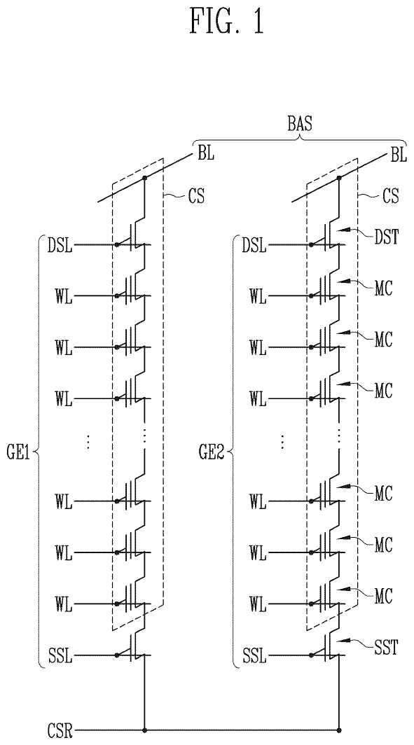

FIG. 1 is a circuit diagram illustrating a memory cell array of a semiconductor memory device according to an embodiment of the present disclosure.

Referring to FIG. 1, the memory cell array of the semiconductor memory device may include a plurality of memory cell strings CS. The plurality of memory cell strings CS may be coupled to gate arrays GE1 and GE2, a bit line array BAS, and a common source layer CSR.

Each memory cell string CS may include at least one source select transistor SST, a plurality of memory cells MC, and at least one drain select transistor DST. The plurality of memory cells MC may be coupled in series between the source select transistor SST and the drain select transistor DST. The source select transistor SST, the plurality of memory cells MC, and the drain select transistor DST may be coupled in series through a channel layer.

A gate array may include a plurality of gate groups. FIG. 1 shows a first gate group GE1 and a second gate group GE2 of the gate array. Each gate group GE1 or GE2 may include a source select line SSL, a plurality of word lines WL, and a drain select line DSL. The source select line SSL may be used as a gate electrode of the source select transistor SST, each word line WL may be used as a gate electrode of a corresponding memory cell MC, and the drain select line DSL may be used as a gate electrode of the drain select transistor DST.

The bit line array BAS may include a plurality of bit lines BL. A voltage for pre-charging the channel layer of a corresponding memory cell string CS may be applied to each bit line BL. A voltage may be applied to the common source layer CSR to discharge a channel layer potential of the memory cell string CS.

The plurality of memory cell strings CS may be coupled in parallel to the common source layer CSR. The plurality of memory cell strings CS may be divided into a plurality of columns and a plurality of rows. To each bit line BL, memory cell strings on a column corresponding to the bit line may be coupled in parallel. To each gate group GE1 or GE2, memory cell strings on a row corresponding to the gate group may be coupled in parallel.

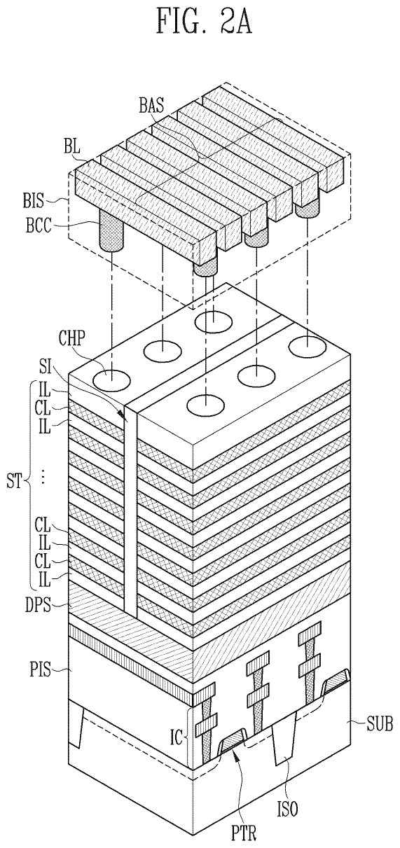

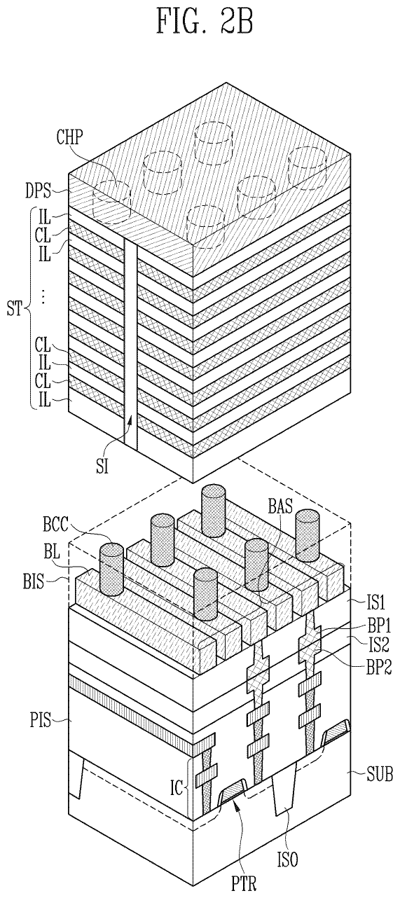

FIGS. 2A and 2B are diagrams illustrating a semiconductor memory device according to embodiments of the present disclosure.

Referring to FIGS. 2A and 2B, the semiconductor memory device may include the bit line array BAS, described with reference to FIG. 1, and a doped semiconductor structure DPS. Each gate group GE1 or GE2, described with reference to FIG. 1, may be composed of a plurality of conductive layers CL of a corresponding gate stacked body ST, among the plurality of gate stacked bodies ST. Each conductive layer CL may include various conductive materials, such as a doped semiconductor layer and a metal layer. The doped semiconductor layer may include a doped silicon layer. The metal layer may include tungsten, copper, molybdenum, etc. The conductive layer CL may further include a conductive metal nitride layer. The conductive metal nitride layer may include titanium nitride, tantalum nitride, etc.

Each gate stacked body ST may further include a plurality of interlayer insulating structures IL that are alternately stacked with the plurality of conductive layers CL between the bit line array BAS and the doped semiconductor structure DPS. Each interlayer insulating structure IL may include an insulating material, such as a silicon oxide layer or a silicon nitride layer. For example, the silicon nitride layer may include a silicon oxynitride layer.

The doped semiconductor structure DPS may include at least one doped semiconductor layer. The doped semiconductor structure DPS may include at least one of an n-type impurity and a p-type impurity. The doped semiconductor structure DPS may be used as at least one of a well area and the common source layer CSR, which is described with reference to FIG. 1. The doped semiconductor structure DPS may include at least one of a first conductivity type doped area including the n-type impurity as a majority carrier and a second conductivity type doped area including the p-type impurity as a majority carrier. The first conductivity type doped area may be provided as the common source layer, and the second conductivity type doped area may be provided as the well area.

The plurality of bit lines BL of the bit line array BAS may be disposed within a bit line insulating structure BIS. FIGS. 2A and 2B are perspective views showing the bit line insulating structure BIS for the convenience of recognition. The plurality of bit lines BL may be spaced apart from the gate stacked body ST with the bit line insulating structure BIS interposed therebetween.

The bit line insulating structure BIS may include multiple insulating layers having two or more layers. The plurality of bit line coupling structures BCC may be further disposed within the bit line insulating structure BIS. The plurality of bit line coupling structures BCC may be disposed between the bit line array BAS and the gate stacked body ST. Each bit line coupling structure BCC may be a conductive pattern coupled to a corresponding bit line BL and may be formed in various structures.

Adjacent gate stacked bodies ST may be spaced apart from each other by a slit SI. A filler disposed in the slit SI may be designed in various ways. According to an embodiment, the filler may include an insulating layer. According to another embodiment, the filler may further include at least one of a conductive layer and a semiconductor layer, in addition to the insulating layer.

The plurality of conductive layers CL of the gate stacked body ST may extend in a direction that intersects with the plurality of bit lines BL. At least one of the plurality of conductive layers CL adjacent to the doped semiconductor structure DPS may be used as the source select line SSL as shown in FIG. 1, at least one layer adjacent to the bit line array BAS may be used as the drain select line DSL as shown in FIG. 1, and the remaining layers may be used as the plurality of word lines WL as shown in FIG. 1.

The plurality of conductive layers CL and the plurality of interlayer insulating structures IL of the gate stacked body ST may extend to enclose a plurality of channel pillars CHP. Each channel pillar CHP may include the channel layer of the memory cell string CS described with reference to FIG. 1. The channel layer of the channel pillar CHP may be electrically connected to a corresponding bit line BL through the bit line coupling structure BCC. The channel layer of the channel pillar CHP may include a contact surface that contacts the doped semiconductor structure DPS. The contact surface may be defined as a portion of a sidewall of the channel pillar CHP, an end of the channel pillar CHP, etc. According to an embodiment, referring to FIG. 2B, the doped semiconductor structure DPS may include a groove into which the end of the channel pillar CHP is inserted, and the contact surface between the doped semiconductor structure DPS and the channel layer may be defined as an end of the channel pillar CHP.

Referring to FIGS. 2A and 2B, the memory cell string of the semiconductor memory device may be defined along the channel pillar CHP. The semiconductor memory device may further include a peripheral circuit structure to control the operation of the memory cell string. The peripheral circuit structure may include an input/output circuit, a control circuit, a voltage generation circuit, a row decoder, a column decoder, a page buffer, etc. To be more specific, the peripheral circuit structure may include a plurality of transistors PTR, a capacitor, a resistor, etc. Although FIGS. 2A and 2B representatively show the plurality of transistors PTR constituting a page buffer coupled to the bit line array BAS, the peripheral circuit structure is not limited to the drawings.

The peripheral circuit structure including the plurality of transistors PTR may be adjacent to the doped semiconductor structure DPS as shown in FIG. 2A or may be adjacent to the bit line array structure BAS as shown in FIG. 2B.

The peripheral circuit structure may be coupled to the memory cell string through the plurality of conductive layers CL, the bit line array structure BAS, and the doped semiconductor structure DPS. According to an embodiment, the transistor PTR of the page buffer may be coupled to the channel layer of the channel pillar CHP through a corresponding bit line BL.

Each transistor PTR may be disposed on an active area of a semiconductor substrate SUB that is partitioned by an isolation layer ISO. A peripheral insulating structure PIS may cover the transistor PTR and the semiconductor substrate SUB on which the transistor PTR is disposed. The transistor PTR may be coupled to the bit line BL through a corresponding interconnection IC. The interconnection IC may be formed in the peripheral insulating structure PIS. The interconnection IC may include at least one of a plurality of conductive lines and a plurality of conductive contacts for providing the electrical connection.

Referring to FIG. 2A, the doped semiconductor structure DPS may be disposed over the peripheral insulating structure PIS. Although not shown in the drawing, the interconnection IC may be electrically connected to the bit line BL through a peripheral circuit contact between the bit line BL and the interconnection IC.

Referring to FIG. 2B, a first conductive bonding structure BP1 and a second conductive bonding structure BP2 may be disposed between the bit line array BAS and the interconnection IC. The first conductive bonding structure BP1 may be disposed in a first intervening insulating structure IS1 between the bit line insulating structure BIS and the peripheral insulating structure PIS. The first conductive bonding structure BP1 may be coupled to a corresponding bit line BL. The second conductive bonding structure BP2 may be disposed in a second intervening insulating structure IS2 between the first intervening insulating structure IS1 and the peripheral insulating structure PIS. The second conductive bonding structure BP2 may be coupled to a corresponding interconnection IC. The first conductive bonding structure BP1 and the second conductive bonding structure BP2 may be bonded to each other, which allows for the interconnection IC and the bit line BL to be electrically connected through the first conductive bonding structure BP1 and the second conductive bonding structure BP2.

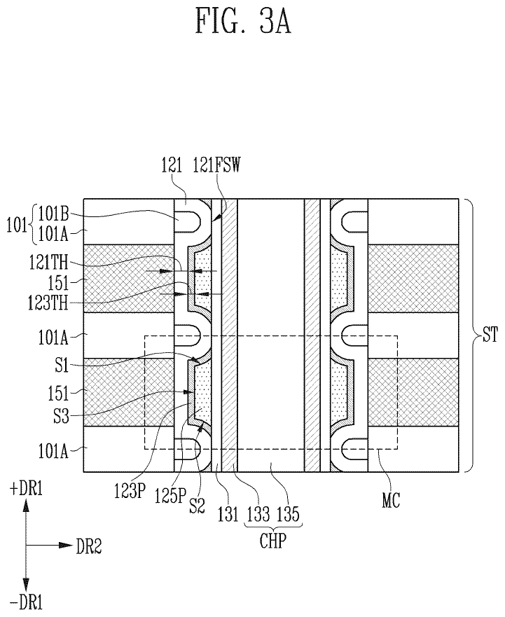

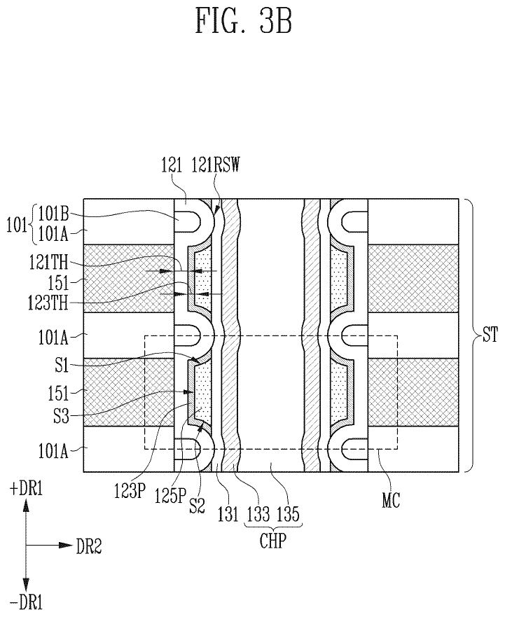

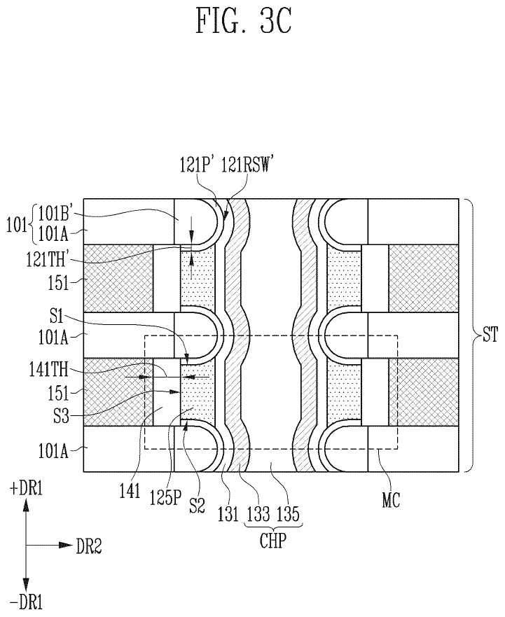

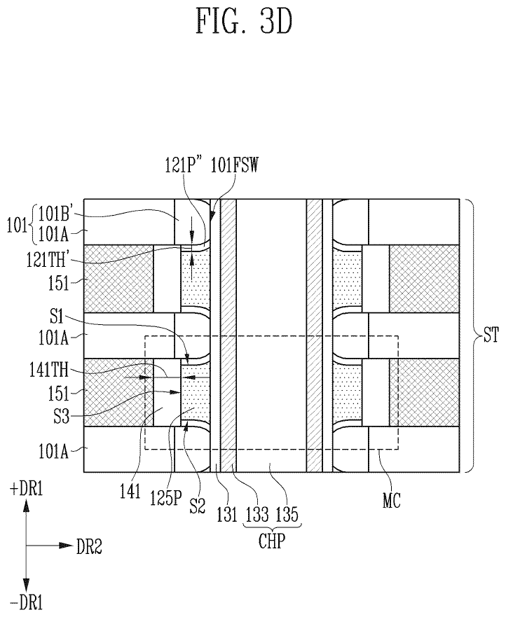

Referring to FIG. 2A or 2B, a data storage layer, used as a data storage area of the memory cell, may be disposed between the conductive layer, used as the word line, among the plurality of conductive layers CL, and the channel pillar CHP. According to embodiments of the present disclosure, it is possible to reduce interference between memory cells adjacent to each other in the stacking direction of the conductive layers CL by separating the data storage layer into a plurality of data storage patterns corresponding to the plurality of memory cells of the memory cell string. Hereinafter, the stacked structure of the plurality of memory cells MC according to embodiments of the present disclosure will be described with reference to the cross-section of the gate stacked body ST and the cross-section of the channel pillar CHP, which are shown in FIGS. 3A to 3D.

FIGS. 3A to 3D are sectional views illustrating the stacked structure of the plurality of memory cells according to embodiments of the present disclosure.

Referring to FIGS. 3A to 3D, the channel layer 133 of the channel pillar CHP may extend in a first direction +DR1. The channel layer 133 may be formed of a semiconductor material, such as silicon (Si), germanium (Ge) or a mixture thereof, which may be used for a channel area of the memory cell string.

The channel pillar CHP may further include a core insulating layer 135. The channel layer 133 may enclose a sidewall of the core insulating layer 135.

The plurality of memory cells MC may be stacked in the first direction +DR1 along the channel layer 133. Each conductive layer 151 of the gate stacked body ST may be used as the word line coupled to a corresponding memory cell MC. Each memory cell MC may include a data storage pattern 125P between a corresponding conductive layer 151 and the channel layer 133. The data storage pattern 125P may be formed of a material layer that may store changed data by using Fowler-Nordheim tunneling. According to an embodiment, the data storage pattern 125P may be formed of a charge trap insulating layer, a floating gate layer, or an insulating layer containing conductive nanodots. The charge trap insulating layer may include a silicon nitride layer.

The plurality of data storage patterns 125P corresponding to the plurality of memory cells MC may be arranged to be spaced apart from each other in the first direction +DR1. Thus, because interference between adjacent memory cells MC in the first direction +DR1 may be reduced, the operational reliability of the semiconductor memory device may be improved.

A tunnel insulating layer 131 may be disposed between each data storage pattern 125P and the channel layer 133. The tunnel insulating layer 131 may extend along an outer wall of the channel layer 133 in the first direction +DR1. The tunnel insulating layer 131 may include an insulating material, such as a silicon oxide layer.

The plurality of data storage patterns 125P may correspond to a plurality of conductive layers 151, respectively. Each data storage pattern 125P may be interposed between a corresponding conductive layer 151 and the tunnel insulating layer 131. The inner wall of the data storage pattern 125P may contact the tunnel insulating layer 131. The data storage pattern 125P may further include a first surface S1, a second surface S2, and a third surface S3, in addition to the above-described inner wall. The first surface S1 may face the first direction +DR1, the second surface S2 may face a direction-DR1 opposite to the first surface S1, and the third surface S3 may face a corresponding conductive layer 151. A blocking insulating layer 121 or a blocking insulation pattern 141 may be disposed between the data storage pattern 125P and the conductive layer 151.

The plurality of interlayer insulating structures 101 of the gate stacked body ST may be arranged along the outer wall of the tunnel insulating layer 131. The plurality of interlayer insulating structures 101 may be disposed to be spaced apart from each other in the first direction +DR1. The plurality of interlayer insulating structures 101 and the plurality of conductive layers 151 may be alternately disposed in the first direction +DR1. Each interlayer insulating structure 101 may include a first interlayer insulating layer 101A and a second interlayer insulating layer 101B or 101B′. The plurality of first interlayer insulating layers 101A of the plurality of interlayer insulating structures 101 and the plurality of conductive layers 151 may be alternately disposed in the first direction +DR1. In other words, each conductive layer 151 may be disposed between adjacent first interlayer insulating layers 101A in the first direction +DR1. The plurality of second interlayer insulating layers 101B or 101B′ of the plurality of interlayer insulating structures 101 may be disposed on sidewalls of the plurality of first interlayer insulating layers 101A. Each second interlayer insulating layer 101B or 101B′ may be disposed between a corresponding first interlayer insulating layer 101A and the tunnel insulating layer 131. Each of the first interlayer insulating layer 101A and the second interlayer insulating layer 101B or 101B′ may have a thickness extending in the first direction +DR1. The thickness of the second interlayer insulating layer 101B or 101B′ may have a maximum value at the point at which the first interlayer insulating layer 101A contacts the second interlayer insulating layer 101B or 101B′.

Referring to FIGS. 3A and 3B, the blocking insulating layer 121 may extend in the first direction +DR1 and may be shaped by the contours of the data storage pattern 125P, the conductive layer 151, the second interlayer insulating layer 101B or 101B′, and the first interlayer insulating layer 101A. Specifically, the blocking insulating layer 121 may extend from a space between each of the first surface S1 and the second surface S2 of the data storage pattern 125P and a corresponding second interlayer insulating layer 101B. The second interlayer insulating layer 101B may include a convex sidewall facing the tunnel insulating layer 131. The blocking insulating layer 121 may extend to a space between the convex sidewall of the second interlayer insulating layer 101B and the tunnel insulating layer 131. A portion of the blocking insulating layer 121 between the convex sidewall of the second interlayer insulating layer 101B and the tunnel insulating layer 131 may include a sidewall 121FSW or 121RSW contacting the tunnel insulating layer 131 between adjacent data storage patterns 125P in the first direction +DR1. According to an embodiment, as shown in FIG. 3A, the sidewall 121FSW of the blocking insulating layer 121 may be flat. According to an embodiment, as shown in FIG. 3B, the sidewall 121RSW of the blocking insulating layer 121 may be rounded.

Referring to FIGS. 3A and 3B, the plurality of data storage patterns 125P may be formed by etching a portion of the data storage layer before forming the tunnel insulating layer 131. In order to protect the blocking insulating layer 121 during the process of etching a portion of the data storage layer, a crystalline insulating layer having a higher etch selectivity to the data storage layer than the blocking insulating layer 121 may be deposited before forming the data storage layer. The crystalline insulating layer may be separated into a plurality of liner insulation patterns 123P. Thus, the occurrence of leakage current due to the crystalline insulating layer may be reduced or prevented. The plurality of liner insulation patterns 123P may be spaced apart from each other in the first direction +DR1 due to a plurality of contact areas between the blocking insulating layer 121 and the tunnel insulating layer 131. The plurality of liner insulation patterns 123P may correspond to the plurality of data storage patterns 125P. The plurality of liner insulation patterns 123P may face the plurality of conductive layers 151 and the plurality of interlayer insulating structures 101 with the blocking insulating layer 121 therebetween. In other words, the blocking insulating layer 121 may be interposed between each of the plurality of conductive layers 151 and the plurality of interlayer insulating structures 101 and a corresponding liner insulation pattern 123P.

The gate stacked body ST may include an inner wall facing the channel layer 133. The inner wall of the gate stacked body ST may have an uneven structure defined by the plurality of conductive layers 151 and the plurality of interlayer insulating structures 101. The blocking insulating layer 121 may be deposited to a first thickness 121TH on the uneven structure formed on the inner wall of the gate stacked body ST. The liner insulation pattern 123P may remain on the inner wall of the blocking insulating layer 121 with a second thickness 123TH. The second thickness 123TH may be less than the first thickness 121TH. A maximum thickness of the second interlayer insulating layer 101B in the first direction +DR1 may be formed to be less than a thickness of the first interlayer insulating layer 101A. Thus, a space in which the blocking insulating layer 121, the liner insulation pattern 123P, and the data storage pattern 125P are to be disposed may be secured between adjacent second interlayer insulating layers 101B in the first direction +DR1.

The liner insulation pattern 123P may include a crystalline high dielectric layer having a higher dielectric constant than a silicon dioxide layer (SiO₂). According to an embodiment, the liner insulation pattern 123P may include a crystalline aluminum oxide layer, a crystalline hafnium oxide layer, etc.

Referring to FIGS. 3C and 3D, the plurality of conductive layers 151 may be alternately disposed with the plurality of first interlayer insulating layers 101A of the plurality of interlayer insulating structures 101 in the first direction +DR1. The plurality of data storage patterns 125P may be alternately disposed with the plurality of second interlayer insulating layers 101B′ of the plurality of interlayer insulating structures 101 in the first direction +DR1.

After the plurality of data storage patterns 125P are separated from each other, the plurality of blocking insulation patterns 141 may be formed. Thus, damage to the plurality of blocking insulation patterns 141 due to an etching process that separates the plurality of data storage patterns 125P can be prevented.

Each blocking insulation pattern 141 may be formed before forming the conductive layer 151 and may be formed by modifying a preliminary layer that is selectively deposited on the third surface S3 of a corresponding data storage pattern 125P. The preliminary layer may include silicon oxycarbide (SiOC) or the same material as the data storage pattern 125P. The blocking insulation pattern 141, which is formed of the modified preliminary layer, may include a low dielectric layer having a lower dielectric constant than the silicon dioxide layer. According to an embodiment, the blocking insulation pattern 141 may include silicon oxycarbide or an oxide of the same material as the data storage pattern 125P.

Before forming the plurality of data storage patterns 125P, a sacrificial insulating layer may be deposited on the surface of the uneven structure defined by the plurality of second interlayer insulating layers 101B′ of the gate stacked body ST. The sacrificial insulating layer may be separated into a plurality of sacrificial insulation patterns 121P′ or 121P″. Each sacrificial insulation pattern 121P′ or 121P″ may be formed to open the third surface S3 of the data storage pattern 125P. The sacrificial insulation pattern 121P′ or 121P″ may cover each of the first surface S1 and the second surface S2 of the data storage pattern 125P. The sacrificial insulation pattern 121P′ or 121P″ may be interposed between the data storage pattern 125P and the second interlayer insulating layer 101B′ adjacent to each other in the first direction +DR1 and may extend along the surface of the second interlayer insulating layer 101B′.

The blocking insulation pattern 141 may be formed on the third surface S3 of the data storage pattern 125P with a first thickness 141TH. The sacrificial insulation pattern 121P′ or 121P″ may be formed on the surface of the second interlayer insulating layer 101B′ with a second thickness 121TH′. The first thickness 141TH may be greater than the second thickness 121TH′.

Referring to FIGS. 3C and 3D, the blocking insulation pattern 141 may be disposed between adjacent first interlayer insulating layers 101A in the first direction +DR1. The blocking insulation pattern 141 might not extend to a space between the second interlayer insulating layer 101B′ and the data storage pattern 125P. Thus, even if the maximum thickness of the second interlayer insulating layer 101B′ in the first direction +DR1 is substantially the same as the first interlayer insulating layer 101A, it is possible to secure a space in which the data storage pattern 125P is to be disposed between adjacent second interlayer insulating layers 101B′ in the first direction +DR1. According to an embodiment, the second interlayer insulating layer 101B′ may contact the sacrificial insulation pattern 121P′ or 121P″, and the sacrificial insulation pattern 121P′ may contact the data storage pattern 125P.

Referring to FIG. 3C, the second interlayer insulating layer 101B′ may include a convex rounded sidewall facing the tunnel insulating layer 131. The sacrificial insulation pattern 121P′ may extend to a space between the rounded sidewall of the second interlayer insulating layer 101B′ and the tunnel insulating layer 131. The sacrificial insulation pattern 121P′ may have a rounded sidewall 121RSW′ facing the tunnel insulating layer 131. The rounded sidewall 121RSW′ may contact the tunnel insulating layer 131.

Referring to FIG. 3D, a sidewall of at least one of the sacrificial insulation pattern 121P″ and the second interlayer insulating layer 101B′ may be planarized. According to an embodiment, the second interlayer insulating layer 101B′ may include a flat sidewall 101FSW facing the tunnel insulating layer 131. The flat sidewall 101FSW may contact the tunnel insulating layer 131.

Referring to FIGS. 3A to 3D, the conductive layer 151, the interlayer insulating structure 101, the channel layer 133, and the like are shown as being separated into adjacent first and second structures in the second direction DR2 with respect to the core insulating layer 135. Although not shown in the drawings, the first structure and the second structure might not be separated from each other but may be coupled to each other by a portion extending along a periphery of the channel pillar CHP as in the interlayer insulating structure IL, shown in FIG. 2A.

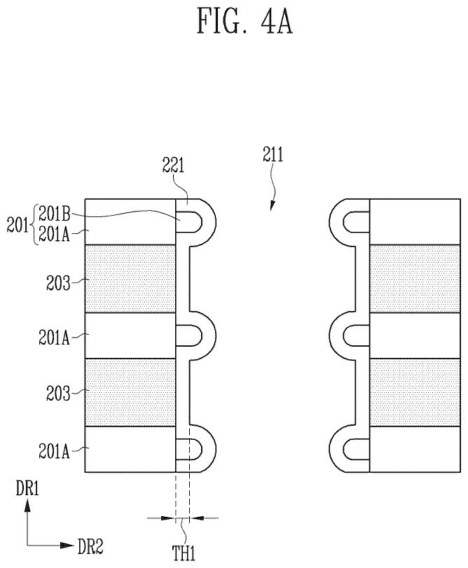

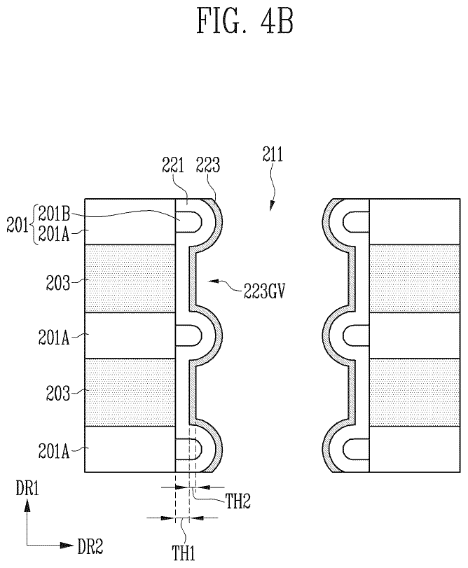

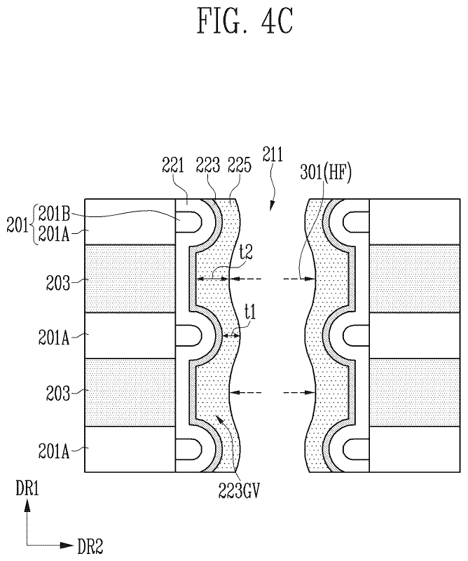

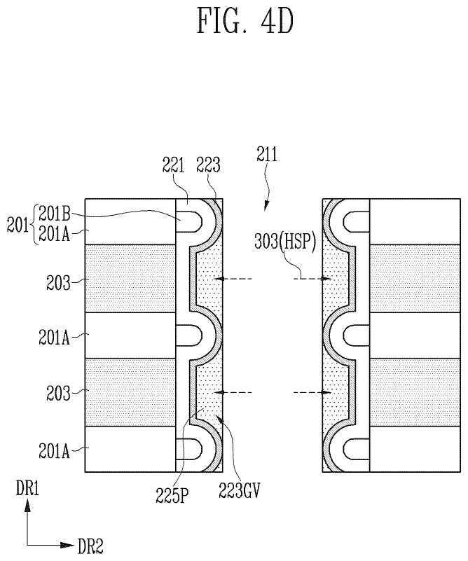

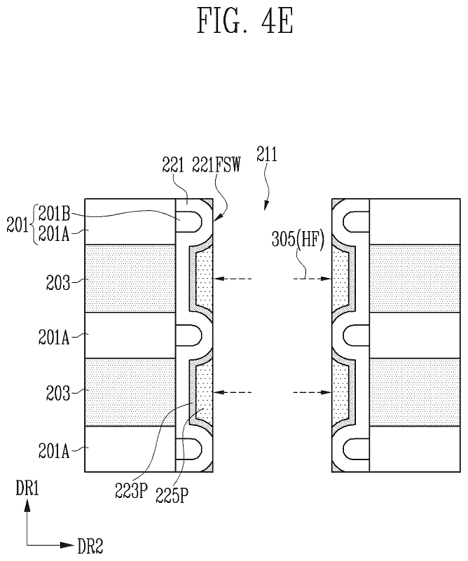

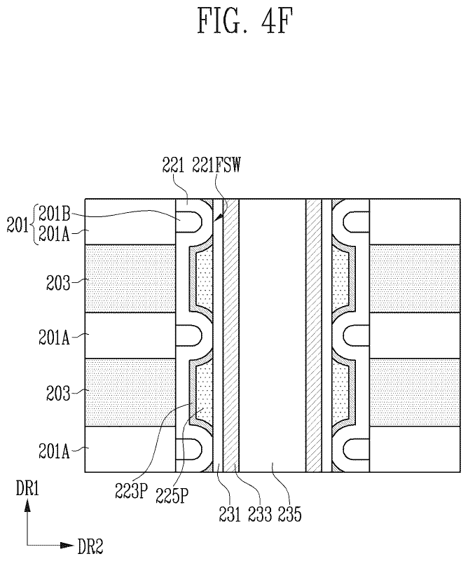

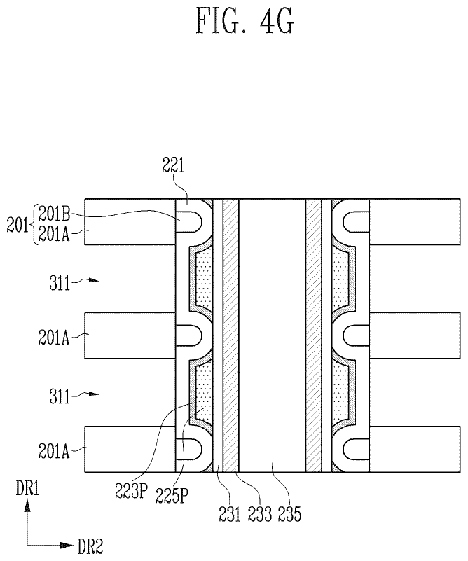

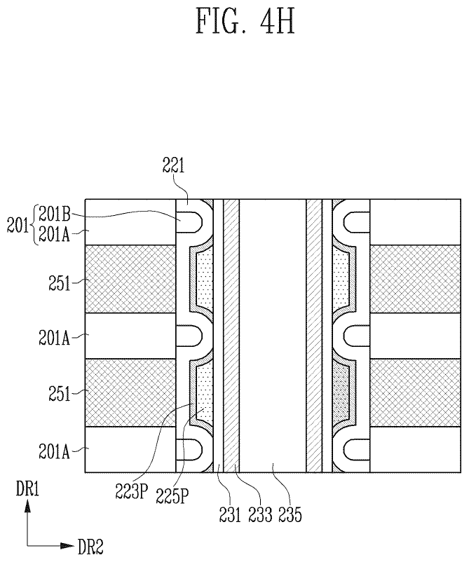

FIGS. 4A to 4H are sectional views illustrating a method of manufacturing a semiconductor memory device according to an embodiment of the present disclosure.

Referring to FIG. 4A, a plurality of first interlayer insulating layers 201A and a plurality of sacrificial layers 203 may be alternately stacked over a lower structure (not shown) in the first direction DR1. The plurality of first interlayer insulating layers 201A and the plurality of sacrificial layers 203 each may have the shape of a plate extending in the second direction DR2 intersecting the first direction DR1.

Although not shown in the drawing, according to an embodiment, the lower structure may include a semiconductor substrate SUB including a plurality of transistors PTR, shown in FIG. 2A, and a doped semiconductor structure DSP, shown in FIG. 2A. According to an embodiment, the lower structure may be a sacrificial substrate formed of a silicon wafer or the like.

The plurality of sacrificial layers 203 may be formed of a material having an etch selectivity with respect to the plurality of first interlayer insulating layers 201A. According to an embodiment, each first interlayer insulating layer 201A may include an insulating material, such as a silicon oxide layer or a silicon oxynitride layer, and each sacrificial layer 203 may include a sacrificial insulating material, such as a silicon nitride layer (SiₓN_{y}, for example, Si₃N₄).

Subsequently, a hole 211 extending in the first direction DR1 may be formed to pass through the plurality of first interlayer insulating layers 201A and the plurality of sacrificial layers 203. Thus, sidewalls of the plurality of first interlayer insulating layers 201A facing the hole 211 may be exposed.

Thereafter, a plurality of second interlayer insulating layers 201B may be formed on the exposed sidewalls of the plurality of first interlayer insulating layers 201A to define an uneven portion on a sidewall of the hole 211. According to an embodiment, the plurality of second interlayer insulating layers 201B may be formed by selectively depositing an insulating material on the sidewalls of the plurality of first interlayer insulating layers 201A. At this time, each second interlayer insulating layer 201B may have a sidewall that is convex in relation to the hole 211. Subsequently, by selectively etching each second interlayer insulating layer 201B, a maximum thickness of the second interlayer insulating layer 201B in the first direction DR1 may be controlled to be less than the first interlayer insulating layer 201A. The first interlayer insulating layer 201A and the second interlayer insulating layer 201B, connected to each other, may form the interlayer insulating structure 201.

A blocking insulating layer 221 may be formed along the uneven portion of the sidewall of the hole 211 defined by the plurality of second interlayer insulating layers 201B. The blocking insulating layer 221 may extend to cover the sidewalls of the plurality of second interlayer insulating layers 201B and the sidewalls of the plurality of sacrificial layers 203. The blocking insulating layer 221 may be deposited on the uneven portion of the sidewall of the hole 211 to have the first thickness TH1. The blocking insulating layer 221 may include an inner wall facing the hole 211. An uneven structure may be defined on the inner wall of the blocking insulating layer 221. The blocking insulating layer 221 may include an insulating material, such as a silicon oxide layer, an aluminum oxide layer, or a hafnium oxide layer.

Referring to FIG. 4B, a crystalline insulating layer 223 may be formed on the inner wall of the blocking insulating layer 221. The crystalline insulating layer 223 may be deposited on the inner wall of the blocking insulating layer 221 to have a second thickness TH2. The second thickness TH2 may be less than the first thickness TH1.

The crystalline insulating layer 223 may include a crystalline high dielectric layer having a higher dielectric constant than a silicon dioxide layer. According to an embodiment, the formation of the crystalline insulating layer 223 may include a step of forming a high dielectric layer, such as an aluminum oxide layer or a hafnium oxide layer, and a step of heat-treating and crystallizing the high dielectric layer.

The crystalline insulating layer 223 may include an inner wall facing the hole 211. The uneven portion defined by the plurality of second interlayer insulating layers 201B may define the plurality of grooves 223GV in the inner wall of the crystalline insulating layer 223. The plurality of grooves 223GV may correspond to the plurality of sacrificial layers 203, respectively.

Referring to FIG. 4C, a data storage layer 225 may be formed on the inner wall of the crystalline insulating layer 223. The data storage layer 225 may fill the plurality of grooves 223GV. The data storage layer 225 may be formed on the convex inner wall of the crystalline insulating layer 223 to have a first thickness t1 in the second direction DR2 and may be formed to have a second thickness t2 inside each groove 223GV, the second thickness t2 being greater than the first thickness t1. The data storage layer 225 may be formed of a charge trap insulating layer, such as a silicon nitride layer, a floating gate layer, such as polysilicon, or an insulating layer containing conductive nanodots.

Subsequently, a portion of the data storage layer 225 may be etched using a first etchant 301. Thus, the thickness of the data storage layer 225 may be reduced. According to an embodiment, hydrofluoric acid (HF) may be used as the first etchant 301. The crystalline insulating layer 223 may reduce or prevent fluorine generated during an etching process using hydrofluoric acid (HF) from penetrating into the blocking insulating layer 221. Thus, damage to the blocking insulating layer 221 may be prevented or mitigated.

Referring to FIG. 4D, by selectively etching the data storage layer using a second etchant 303, the data storage layer may be separated into a plurality of data storage patterns 225P. Each data storage pattern 225P may remain in a corresponding groove 223GV.

The second etchant 303 may have a higher etch selectivity compared to the first etchant 301 to avoid etching the blocking insulating layer 221 and the crystalline insulating layer 223 while etching the data storage layer 225. According to an embodiment, the second etchant 303 may be high selectivity phosphoric acid (HSP). By selectively etching the data storage layer 225 using the second etchant 303 after reducing the thickness of the data storage layer 225 using the first etchant 301, shown in FIG. 4C, the concentration of by-products generated during the etching process using the second etchant 303 may be controlled below a critical value. Thus, when the concentration of the by-products in the second etchant 303 with a high selectivity, such as phosphoric acid (H₃PO₄), exceeds a critical value, the phenomenon of oxide regrowth may be prevented or mitigated.

During the etching process of the data storage layer using the second etchant 303, a portion of the crystalline insulating layer 223 may be exposed. The portion of the crystalline insulating layer 223 may be exposed between adjacent data storage patterns 225P in the first direction DR1.

Referring to FIG. 4E, by etching the exposed portion of the crystalline insulating layer, the crystalline insulating layer may be separated into the plurality of liner insulation patterns 223P. Thus, a portion of the blocking insulating layer 221 may be exposed between adjacent liner insulation patterns 223P in the first direction DR1. The exposed portion of the blocking insulating layer 221 may correspond to a rounded sidewall facing the hole 211.

Subsequently, the rounded sidewall of the blocking insulating layer 221 may be planarized through a trimming process. The trimming process may include the etching process using the third etchant 305. Hydrofluoric acid (HF) may be used as a third etchant 305. A portion of the data storage pattern 225P may be etched by hydrofluoric acid (HF). A phenomenon in which fluorine produced during the etching process using hydrofluoric acid (HF) penetrates the blocking insulating layer 221 between the sacrificial layer 203 and the data storage pattern 225P may be prevented or mitigated by the liner insulation pattern 223P.

Through the trimming process, the blocking insulating layer 221 may have a flat sidewall 221FSW.

Referring to FIG. 4F, a tunnel insulating layer 231 may be formed in a hole 211 (see FIG. 4E). The tunnel insulating layer 231 may include an insulating material, such as a silicon oxide layer. The tunnel insulating layer 231 may extend in the first direction DR1 to cover the flat sidewall 221FSW of the blocking insulating layer 221, the plurality of data storage patterns 225P, and the plurality of liner insulation patterns 223P.

Subsequently, a channel layer 233 may be formed along the inner wall of the tunnel insulating layer 231. The channel layer 233 may be formed of a semiconductor material, such as silicon (Si), germanium (Ge) or a mixture thereof. Thereafter, a core insulating layer 235 may be formed in the hole 211 (see FIG. 4E).

Referring to FIG. 4G, a plurality of openings 311 may be defined by removing the plurality of sacrificial layers 203 as shown in FIG. 4F. To this end, the slit SI, shown in FIG. 2A or 2B, may be formed to pass through the plurality of sacrificial layers 203 and the plurality of first interlayer insulating layers 201A as shown in FIG. 4F. The plurality of sacrificial layers 203, shown in FIG. 4F, may be selectively removed through the slit. Each opening 311 may be defined between adjacent first interlayer insulating layers 201A in the first direction DR1.

Referring to FIG. 4H, a plurality of conductive layers 251 may be formed inside the plurality of openings 311 as shown in FIG. 4G. To this end, the plurality of openings 311, shown in FIG. 4G, may be filled with a conductive material through the slit, and a portion of the conductive material in the slit may be removed so that the conductive material is separated into the plurality of conductive layers 251.

Using the processes described with reference to FIGS. 4A to 4H, the semiconductor memory device, shown in FIG. 3A, may be provided.

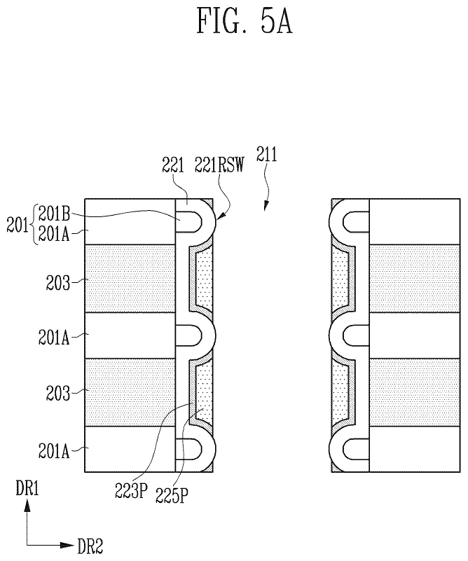

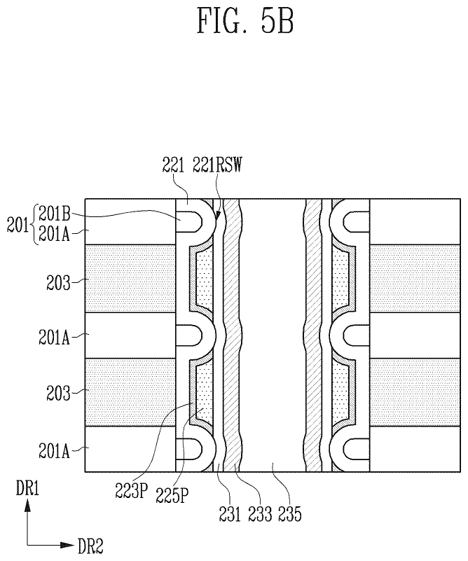

FIGS. 5A and 5B are sectional views illustrating a method of manufacturing a semiconductor memory device according to an embodiment of the present disclosure.

Prior to performing a process shown in FIG. 5A, a process of forming the stacked structure of the plurality of first interlayer insulating layers 201A and the plurality of sacrificial layers 203 described with reference to FIG. 4A, a process of forming the hole 211 that passes through the plurality of first interlayer insulating layers 201A and the plurality of sacrificial layers 203, and a process of forming the plurality of second interlayer insulating layers 201B may be performed. Further, prior to performing the process shown in FIG. 5A, the process of forming the crystalline insulating layer described with reference to FIG. 4B, the process of forming the data storage layer described with reference to FIG. 4C, the process of etching a portion of the data storage layer using the first etchant described with reference to FIG. 4C, and the process of selectively etching the data storage layer with the second etchant described with reference to FIG. 4D may be performed. Thus, as shown in FIG. 5A, the plurality of data storage patterns 225P may be disposed between the plurality of interlayer insulating structures 201 defined by the plurality of first interlayer insulating layers 201A and the plurality of second interlayer insulating layers 201B.

Subsequently, as described with reference to FIG. 4D, a portion of the crystalline insulating layer exposed between the data storage patterns 225P may be etched. Thus, as shown in FIG. 5A, the crystalline insulating layer may be separated into the plurality of liner insulation patterns 223P.

Referring to FIG. 5A, the rounded sidewall 221RSW of the blocking insulating layer 221 may be exposed between adjacent liner insulation patterns 223P in the first direction DR1.

Referring to FIG. 5B, the tunnel insulating layer 231 may be formed inside the hole 211 (see FIG. 5A). The tunnel insulating layer 231 may extend in the first direction DR1 to cover the rounded sidewall 221RSW of the blocking insulating layer 221, the plurality of data storage patterns 225P, and the plurality of liner insulation patterns 223P. Subsequently, the channel layer 233 and the core insulating layer 235 may be sequentially formed.

Subsequently, by performing the processes shown in FIGS. 4G and 4H, the semiconductor memory device as shown in FIG. 3B may be provided.

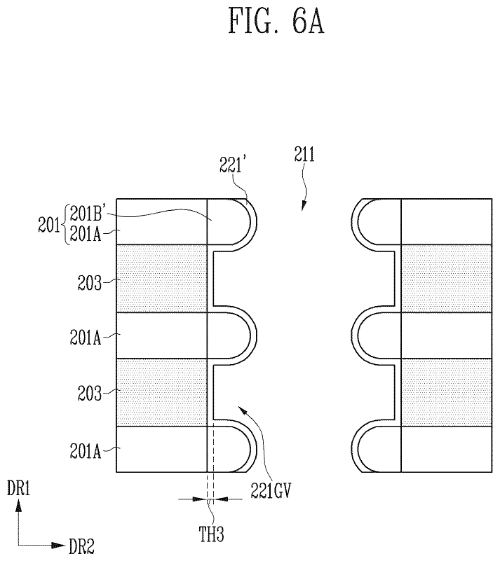

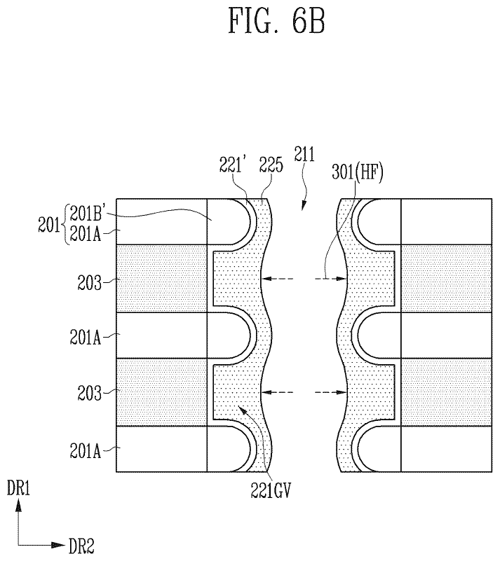

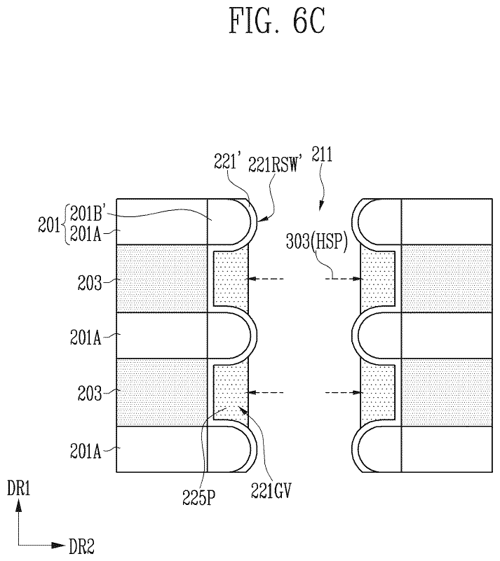

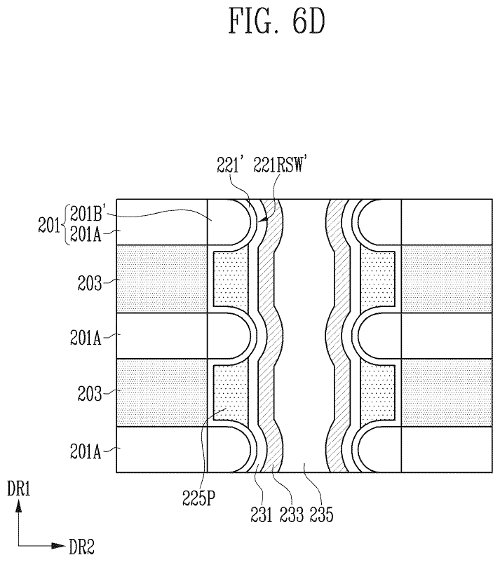

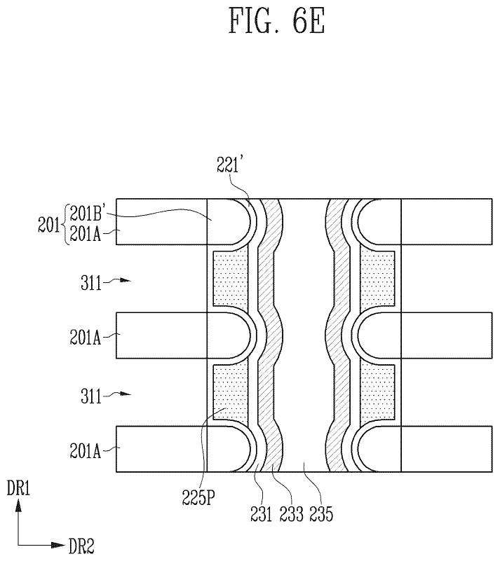

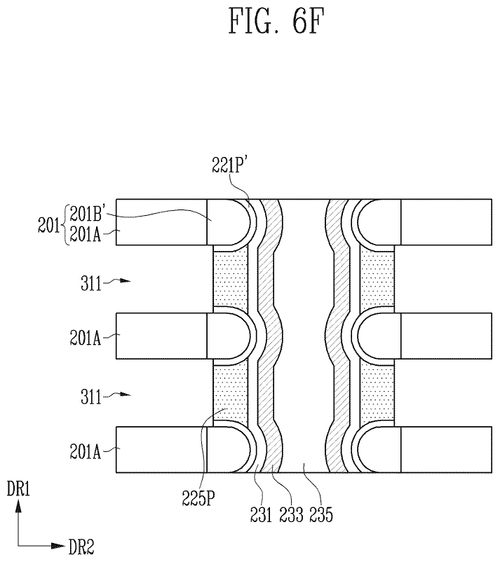

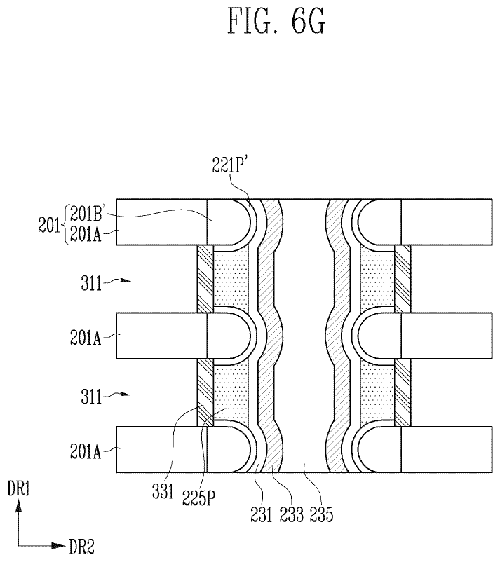

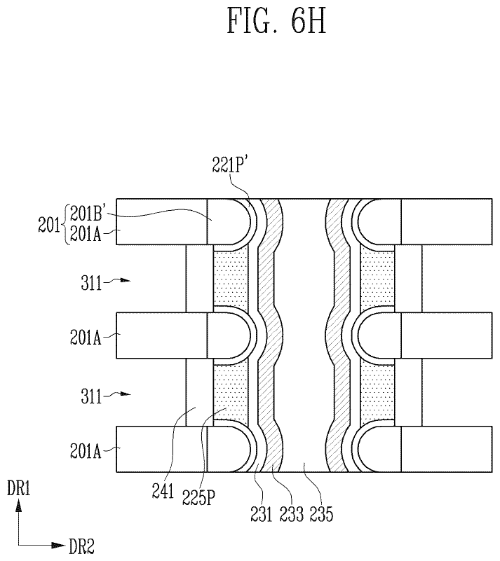

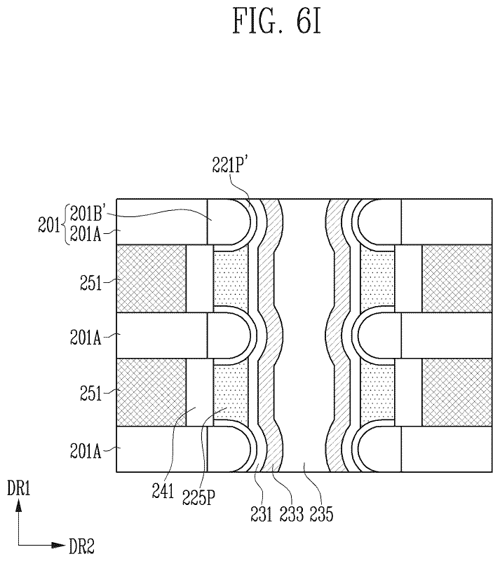

FIGS. 6A to 6I are sectional views illustrating a method of manufacturing a semiconductor memory device according to an embodiment of the present disclosure.

Referring to FIG. 6A, as described with reference to FIG. 4A, the plurality of first interlayer insulating layers 201A and the plurality of sacrificial layers 203 may be alternately stacked over the lower structure (not shown) in the first direction DR1. Each of the plurality of first interlayer insulating layers 201A and the plurality of sacrificial layers 203 may have the shape of a flat plate extending in the second direction DR2, the second direction DR2 intersecting the first direction DR1.

Subsequently, the hole 211 extending in the first direction DR1 to pass through the plurality of first interlayer insulating layers 201A and the plurality of sacrificial layers 203 may be formed. Thus, the sidewalls of the plurality of first interlayer insulating layers 201A facing the hole 211 may be exposed.

Thereafter, a plurality of second interlayer insulating layers 201B′ may be formed on the exposed sidewalls of the plurality of first interlayer insulating layers 201A to define an uneven portion on a sidewall of the hole 211. According to an embodiment, the plurality of second interlayer insulating layers 201B′ may be formed by selectively depositing an insulating material on the sidewalls of the plurality of first interlayer insulating layers 201A. At this time, each second interlayer insulating layer 201B′ may have a sidewall that is convex in relation to the hole 211. The first interlayer insulating layer 201A and the second interlayer insulating layer 201B′ connected to each other may form the interlayer insulating structure 201.

Subsequently, a sacrificial insulating layer 221′ may be formed along the uneven portion of the sidewall of the hole 211 defined by the plurality of second interlayer insulating layers 201B′. The sacrificial insulating layer 221′ may extend to cover sidewalls of the plurality of second interlayer insulating layers 201B′ and sidewalls of the plurality of sacrificial layers 203. The sacrificial insulating layer 221′ may be deposited on the uneven portion of the sidewall of the hole 211 to the third thickness TH3. The third thickness TH3 may be less than the first thickness TH1 of the blocking insulating layer 221 described with reference to FIG. 4A. The sacrificial insulating layer 221′ may include an insulating material, such as a silicon oxide layer.

The sacrificial insulating layer 221′ may include an inner wall facing the hole 211. The uneven portion defined by the plurality of second interlayer insulating layers 201B′ may define a plurality of grooves 221GV on the inner wall of the sacrificial insulating layer 221′. The plurality of grooves 221GV may correspond to the plurality of sacrificial layers 203, respectively.

Referring to FIG. 6B, a data storage layer 225 may be formed on the inner wall of the sacrificial insulating layer 221′. The data storage layer 225 may fill the plurality of grooves 221GV. Similarly to FIG. 4C, the thickness of the data storage layer 225 in the second direction DR2 may be greater inside the grooves 221GV than along the convex inner wall of the sacrificial insulating layer 221′. The data storage layer 225 may be formed of a charge trap insulating layer, such as a silicon nitride layer, a floating gate layer, such as polysilicon, or an insulating layer containing conductive nanodots.

Subsequently, a portion of the data storage layer 225 may be etched using a first etchant 301. Thus, the thickness of the data storage layer 225 may be reduced. According to an embodiment, hydrofluoric acid (HF) may be used as the first etchant 301.

Referring to FIG. 6C, by selectively etching the data storage layer using a second etchant 303, the data storage layer may be separated into a plurality of data storage patterns 225P. Each data storage pattern 225P may remain in a corresponding groove 223GV.

The second etchant 303 may have a higher etch selectivity compared to the first etchant 301 to avoid etching the sacrificial insulating layer 221′ while etching the data storage layer 225. According to an embodiment, the second etchant 303 may be high selectivity phosphoric acid (HSP). By selectively etching the data storage layer 225 using the second etchant 303 after reducing the thickness of the data storage layer 225 using the first etchant 301 as shown in FIG. 6B, the concentration of by-products generated during the etching process using the second etchant 303 may be controlled below a critical value. Thus, when the concentration of the by-products in the second etchant 303 with a high selectivity such as phosphoric acid (H₃PO₄) exceeds a critical value, the phenomenon of oxide regrowth may be prevented or mitigated.

During the etching process of the data storage layer using the second etchant 303, a portion of the sacrificial insulating layer 221′ may be exposed. The portion of the sacrificial insulating layer 221′ may be exposed between adjacent data storage patterns 225P in the first direction DR1. The exposed portion of the sacrificial insulating layer 221′ may be a rounded sidewall 221RSW′ facing the hole 211.

Referring to FIG. 6D, the tunnel insulating layer 231 may be formed inside the hole 211 (see FIG. 6C). The tunnel insulating layer 231 may extend in the first direction DR1 to cover the rounded sidewall 221RSW′ of the sacrificial insulating layer 221′ and the plurality of data storage patterns 225P. The tunnel insulating layer 231 may include an insulating material, such as a silicon oxide layer.

Subsequently, the channel layer 233 and the core insulating layer 235 may be sequentially formed as described with reference to FIG. 4F.

Referring to FIG. 6E, by removing the plurality of sacrificial layers 203, shown in FIG. 6D, as described with reference to FIG. 4G, the plurality of openings 311 may be defined. At this time, the plurality of data storage patterns 225P may be protected by the sacrificial insulating layer 221′. A portion of the sacrificial insulating layer 221′ may be exposed by the plurality of openings 311.

Referring to FIG. 6F, by removing a portion of the sacrificial insulating layer exposed through the plurality of openings 311, the sacrificial insulating layer may be separated into a plurality of sacrificial insulation patterns 221P′. As a portion of the sacrificial insulating layer is removed, the plurality of data storage patterns 225P may be exposed through the plurality of openings 311.

Referring to FIG. 6G, a preliminary layer 331 may be selectively deposited on the exposed surface of each of the plurality of data storage patterns 225P. According to an embodiment, the preliminary layer 331 may be deposited using area-selective atomic layer deposition (ASD) and may include silicon oxycarbide (SiOC).

Referring to FIG. 6H, a blocking insulation pattern 241 may be formed by modifying the preliminary layer 331 as shown in FIG. 6G. According to an embodiment, by annealing silicon oxycarbide, the blocking insulation pattern 241 may be formed. Here, carbon may be removed from the annealed silicon oxycarbide, and a dielectric constant and a thickness may be increased compared to silicon oxycarbide before annealing. The blocking insulation pattern 241 containing the annealed silicon oxycarbide may have a lower dielectric constant than the silicon dioxide layer and may be thicker than the sacrificial insulation pattern 221P′. Because the blocking insulation pattern 241 is formed after separating the data storage layer into the plurality of data storage patterns 225P through the etching process, it is possible to prevent or reduce fluorine produced during the etching process of the data storage layer from penetrating into the blocking insulation pattern 241.

Referring to 6I, a plurality of conductive layers 25I may be formed in the plurality of openings 311 as shown in FIG. 6H. Each conductive layer 25I may face a corresponding data storage pattern 225P with the blocking insulation pattern 241 interposed therebetween.

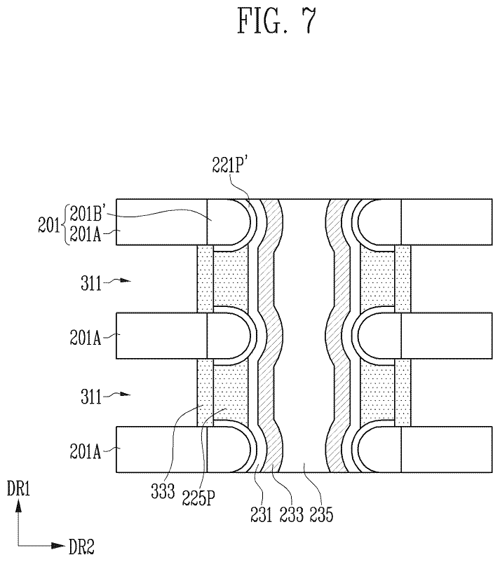

FIG. 7 is a sectional view illustrating a process of forming a preliminary layer according to an embodiment of the present disclosure.

Instead of the preliminary layer 331 shown in FIG. 6G, a preliminary layer 333 shown in FIG. 7 may be formed. The preliminary layer 333 shown in FIG. 7 may include the same material as the plurality of data storage patterns 225P. The preliminary layer 333 may be selectively formed on surfaces of the plurality of data storage patterns 225P exposed by the plurality of openings 311. The preliminary layer 333 may be modified into the blocking insulation pattern 241, shown in FIG. 6H, through oxidation.

Reference numerals “201A”, “201B”, “201”, “221P”, “231”, “233”, and “235”, which are not described in FIG. 7, may refer to the first interlayer insulating layer, the second interlayer insulating layer, the interlayer insulating structure, the sacrificial insulation pattern, the tunnel insulating layer, the channel layer, and the core insulating layer, which are described with reference to FIGS. 6A to 6I, respectively.

The semiconductor memory device shown in FIG. 3C may be provided using the processes described with reference to FIGS. 6A to 6I and FIG. 7.

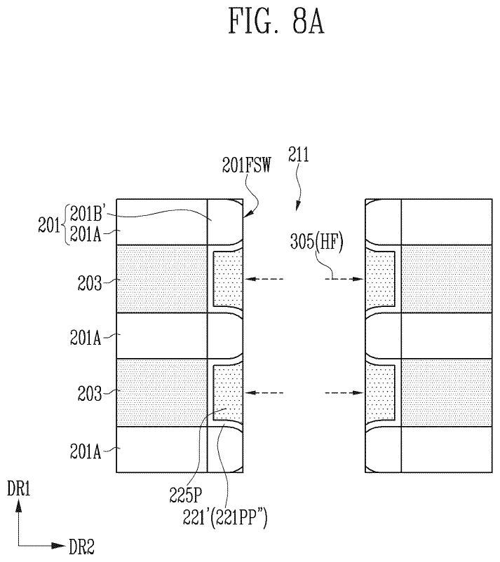

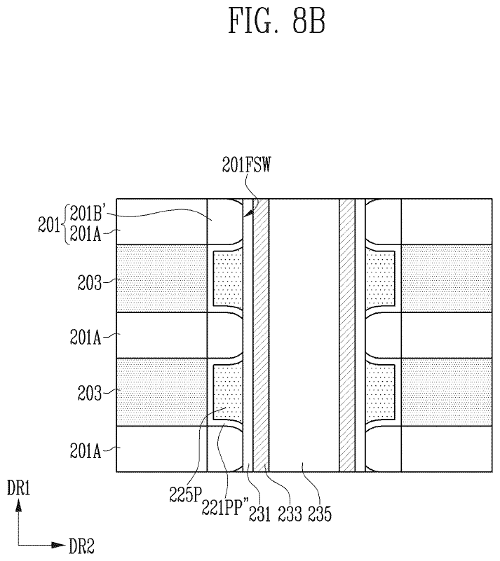

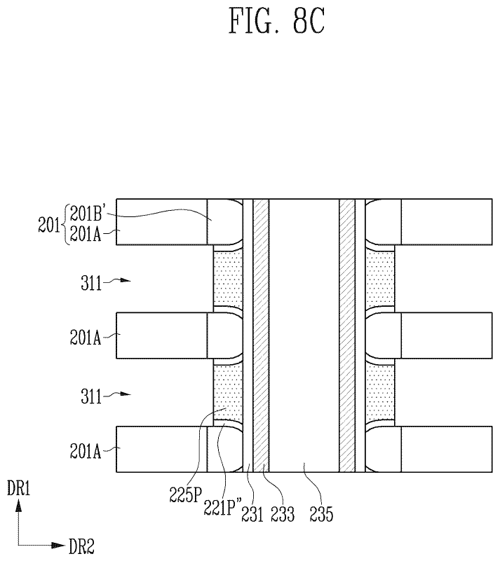

FIGS. 8A to 8C are sectional views illustrating a method of manufacturing a semiconductor memory device according to an embodiment of the present disclosure.

Before performing a process shown in FIG. 8A, a process of forming a structure in which the plurality of first interlayer insulating layers 201A and the plurality of sacrificial layers 203 are alternately stacked as described with reference to FIG. 6A, a process of forming the hole 211 as described with reference to FIG. 6A, a process of selectively forming the plurality of second interlayer insulating layers 201B′ on the sidewalls of the plurality of first interlayer insulating layers 201A to define the plurality of interlayer insulating structures 201, and a process of forming the sacrificial insulating layer 221′ as described with reference to FIG. 6A may be performed. Further, before performing the process shown in FIG. 8A, a process of forming the data storage layer as described with reference to FIG. 6B, a process of reducing the thickness of the data storage layer using the first etchant as described with reference to FIG. 6B, and a process of forming the plurality of data storage patterns 225P as described with reference to FIG. 6C may be sequentially performed. Thus, as shown in FIG. 6C, the rounded sidewall 221RSW′ of the sacrificial insulating layer 221′ may be exposed between adjacent data storage patterns 225P in the first direction DR1.

The rounded sidewall 221RSW′ of the sacrificial insulating layer 221′, shown in FIG. 6C, or the convex sidewall of the second interlayer insulating layer 201B′, shown in FIG. 6C, may be planarized by the trimming process. According to an embodiment, as shown in FIG. 8A, the convex sidewall of the second interlayer insulating layer 201B′, shown in FIG. 6C, may be planarized through the trimming process. Here, the sacrificial insulating layer 221′ may be a plurality of preliminary sacrificial insulation patterns 221PP″, and the second interlayer insulating layer 201B′ may have a flat sidewall 201FSW. The trimming process may include an etching process using a third etchant 305. Hydrofluoric acid (HF) may be used as the third etchant 305. A portion of the data storage pattern 225P may be etched by hydrofluoric acid (HF).

Referring to FIG. 8B, the tunnel insulating layer 231 may be formed inside the hole 211 (see FIG. 8A). The tunnel insulating layer 231 may extend in the first direction DR1 to cover the flat sidewall 201FSW of the second interlayer insulating layer 201B′, the plurality of data storage patterns 225P, and the plurality of preliminary sacrificial insulation patterns 221PP″. Subsequently, the channel layer 233 and the core insulating layer 235 may be sequentially formed.

Referring to FIG. 8C, the plurality of openings 311 may be formed by removing the plurality of sacrificial layers 203 shown in FIG. 8B to expose the plurality of preliminary sacrificial insulation patterns 221PP″ shown in FIG. 8B. Thereafter, the plurality of sacrificial insulation patterns 221P″ may remain by removing a portion of the plurality of preliminary sacrificial insulation patterns 221PP″, shown in FIG. 8B, through the plurality of openings 311. Each sacrificial insulation pattern 221P″ may remain between the data storage pattern 225P and the second interlayer insulating layer 201B′, which are adjacent to each other in the first direction DR1.

Subsequently, the process described with reference to FIGS. 6G and 6H or the process described with reference to FIG. 7 may be performed, and then the process described with reference to FIG. 6I may be performed. Thus, the semiconductor memory device, shown in FIG. 3D, may be provided.

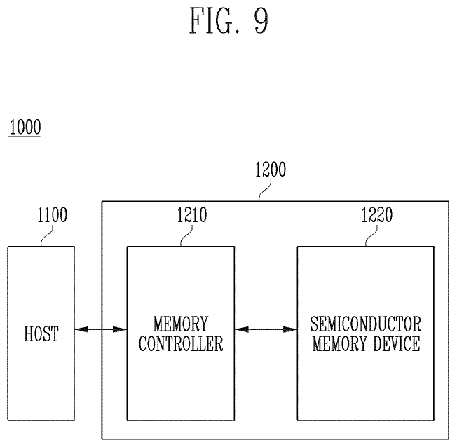

FIG. 9 is a block diagram illustrating an electronic system according to an embodiment of the present disclosure.

Referring to FIG. 9, the electronic system 1000 may be a computing system, a medical device, a communication device, a wearable device, a memory system, etc. The electronic system 1000 may include a host 1100 and a storage device 1200.

The host 1100 may store data in the storage device 1200 or read data stored in the storage device 1200 based on an interface. The interface may include at least one of a Double Data Rate (DDR) interface, an Universal Serial Bus (USB) interface, a multimedia card (MMC) interface, an embedded MMC (eMMC) interface, a peripheral component interconnection (PCI) interface, a PCI-express (PCI-E) interface, an Advanced Technology Attachment (ATA) interface, a Serial-ATA interface, a Parallel-ATA interface, a small computer system interface (SCSI), an enhanced small disk interface (ESDI), an Integrated Drive Electronics (IDE) interface, a Firewire interface, a Universal Flash Storage (UFS) interface, and a Nonvolatile Memory express (NVMe) interface.

The storage device 1200 may include a memory controller 1210 and a semiconductor memory device 1220. According to an embodiment, the storage device 1200 may include the semiconductor memory device 1220, such as a solid state drive (SSD) or a Universal Serial Bus (USB) memory.

The memory controller 1210 may store data in the semiconductor memory device 1220 or read data stored in the semiconductor memory device 1220 under the control of the host 1100.

The semiconductor memory device 1220 may include one memory chip or a plurality of memory chips. The semiconductor memory device 1220 may store data or output the stored data under the control of the memory controller 1210.

The semiconductor memory device 1220 may be a non-volatile memory device. As described with reference to FIGS. 3A to 3D, the semiconductor memory device 1220 may include a plurality of interlayer insulating structures, a plurality of conductive layers that are stacked alternately with the plurality of interlayer insulating structures, a plurality of data storage patterns that are spaced apart from each other in a direction in which the plurality of interlayer insulating structures and the plurality of conductive layers are stacked, and a blocking insulating layer or a blocking insulation pattern interposed between each data storage pattern and a corresponding conductive layer. The semiconductor memory device 1220 may further include a crystalline insulating layer interposed between the blocking insulating layer and the data storage pattern as described with reference to FIGS. 3A and 3B, or a sacrificial insulation pattern interposed between each interlayer insulating structure and a corresponding data storage pattern as described with reference to FIGS. 3C and 3D.

According to an embodiment of the present disclosure, as data storage patterns are spaced from each other in a stacking direction of conductive layers, interference between memory cells can be reduced, so that the operational reliability of a semiconductor memory device can be improved.

What is claimed is:

1. A semiconductor memory device, comprising:
a channel layer extending in a first direction;
a tunnel insulating layer extending along an outer wall of the channel layer in the first direction;
a plurality of interlayer insulating structures arranged along an outer wall of the tunnel insulating layer, the plurality of interlayer insulating structures being spaced apart from each other in the first direction;
a plurality of conductive layers alternately arranged with the plurality of interlayer insulating structures in the first direction;
a plurality of data storage patterns interposed between the plurality of conductive layers and the tunnel insulating layer in a second direction, each of the plurality of data storage patterns being spaced apart from each other in the first direction, wherein the plurality of data storage patterns correspond to the plurality of conductive layers, respectively, and wherein the second direction is perpendicular to the first direction;
a liner insulation pattern extending to cover a first surface of each of the plurality of data storage patterns facing the first direction, a second surface of each of the plurality of data storage patterns facing a direction opposite to the first surface, and a third surface of each of the plurality of data storage patterns facing the second direction; and
a blocking insulating layer interposed between each of the plurality of conductive layers and the liner insulation pattern,
wherein the liner insulation pattern comprises a crystalline insulating layer.

2. The semiconductor memory device according to claim 1, wherein the liner insulation pattern is thinner than the blocking insulating layer.

3. The semiconductor memory device according to claim 1, wherein the liner insulation pattern has a higher dielectric constant than a silicon dioxide layer (SiO₂).

4. The semiconductor memory device according to claim 1, wherein the plurality of interlayer insulating structures comprise:
a plurality of first interlayer insulating layers alternately arranged with the plurality of conductive layers in the first direction; and
a plurality of second interlayer insulating layers interposed between the plurality of first interlayer insulating layers and the tunnel insulating layer, and each having a sidewall that is convex in relation to the tunnel insulating layer.

5. The semiconductor memory device according to claim 4, wherein the blocking insulating layer extends to a space between the plurality of second interlayer insulating layers and the tunnel insulating layer and has a flat sidewall facing the tunnel insulating layer.

6. The semiconductor memory device according to claim 4, wherein the blocking insulating layer extends to a space between the plurality of second interlayer insulating layers and the tunnel insulating layer and has a rounded sidewall facing the tunnel insulating layer.

7. A semiconductor memory device, comprising:
a channel layer extending in a first direction;
a tunnel insulating layer extending along an outer wall of the channel layer in the first direction;
a plurality of interlayer insulating structures arranged along an outer wall of the tunnel insulating layer, the plurality of interlayer insulating structures being spaced apart from each other in the first direction;
a plurality of conductive layers alternately arranged with the plurality of interlayer insulating structures in the first direction;
a plurality of data storage patterns interposed between the plurality of conductive layers and the tunnel insulating layer in a second direction, each of the plurality of data storage patterns being spaced apart from each other in the first direction, wherein the plurality of data storage patterns correspond to the plurality of conductive layers, respectively, and wherein the second direction is perpendicular to the first direction;
a sacrificial insulation pattern covering a first surface of each of the plurality of data storage patterns facing the first direction, and a second surface of each of the plurality of data storage patterns facing a direction opposite to the first surface; and
a blocking insulation pattern interposed between each of the plurality of data storage patterns and a corresponding conductive layer among the plurality of conductive layers,
wherein the blocking insulation pattern is thicker than the sacrificial insulation pattern.

8. The semiconductor memory device according to claim 7, wherein the sacrificial insulation pattern is formed to open a third surface of each of the plurality of data storage patterns facing the second direction.

9. The semiconductor memory device according to claim 7, wherein the blocking insulation pattern has a lower dielectric constant than a silicon dioxide layer.

10. The semiconductor memory device according to claim 7, wherein the blocking insulation pattern comprises silicon oxycarbide (SiOC) or comprises an oxide of the same material as the plurality of data storage patterns.

11. The semiconductor memory device according to claim 7, wherein the plurality of interlayer insulating structures comprise:
a plurality of first interlayer insulating layers alternately arranged with the plurality of conductive layers in the first direction; and
a plurality of second interlayer insulating layers interposed between the plurality of first interlayer insulating layers and the tunnel insulating layer and alternately arranged with the plurality of data storage patterns in the first direction.

12. The semiconductor memory device according to claim 11, wherein the sacrificial insulation pattern is interposed between a second interlayer insulating layer and a data storage pattern that are adjacent to each other in the first direction, among the plurality of second interlayer insulating layers and the plurality of data storage patterns.

13. The semiconductor memory device according to claim 11,
wherein each of the plurality of second interlayer insulating layers has a rounded sidewall facing the tunnel insulating layer, and
wherein the sacrificial insulation pattern extends to a space between the rounded sidewall and the tunnel insulating layer.

14. The semiconductor memory device according to claim 11, wherein each of the plurality of second interlayer insulating layers has a flat sidewall contacting the tunnel insulating layer.

15. A method of manufacturing a semiconductor memory device, the method comprising:
alternately stacking a plurality of first interlayer insulating layers and a plurality of sacrificial layers in a first direction;
forming a hole that passes through the plurality of first interlayer insulating layers and the plurality of sacrificial layers;
forming a plurality of second interlayer insulating layers on sidewalls of the plurality of first interlayer insulating layers facing the hole to define an uneven portion on a sidewall of the hole;
forming a blocking insulating layer along the uneven portion to cover sidewalls of the plurality of second interlayer insulating layers and sidewalls of the plurality of sacrificial layers;
forming a crystalline insulating layer on an inner wall of the blocking insulating layer to have a plurality of grooves corresponding to the plurality of sacrificial layers;
forming a plurality of data storage patterns on an inner wall of the crystalline insulating layer to respectively fill the plurality of grooves of the crystalline insulating layer;
etching a portion of the crystalline insulating layer exposed between the plurality of data storage patterns so that the crystalline insulating layer is separated into a plurality of liner insulation patterns;
forming a tunnel insulating layer inside the hole to cover an area in which the crystalline insulating layer is etched and the plurality of data storage patterns;
forming a channel layer along an inner wall of the tunnel insulating layer; and
replacing the plurality of sacrificial layers with a plurality of conductive layers.

16. The method according to claim 15, wherein the crystalline insulating layer is thinner than the blocking insulating layer.

17. The method according to claim 15, wherein the crystalline insulating layer has a higher dielectric constant than a silicon dioxide layer.

18. The method according to claim 15, wherein forming the plurality of data storage patterns comprises:
forming a data storage layer on the inner wall of the crystalline insulating layer to fill the plurality of grooves of the crystalline insulating layer;
removing a portion of the data storage layer with hydrofluoric acid (HF) to reduce a thickness of the data storage layer; and
removing a portion of the data storage layer with phosphoric acid (H₃PO₄) so that the data storage layer with a reduced thickness is separated into the plurality of data storage patterns.

19. The method according to claim 15, wherein etching the portion of the crystalline insulating layer is performed to expose the blocking insulating layer.

20. The method according to claim 19,
wherein the sidewalls of the plurality of second interlayer insulating layers are convex in relation to the hole,
wherein the exposed area of the blocking insulating layer corresponds to a rounded sidewall facing the hole on the sidewalls of the plurality of second interlayer insulating layers, and
wherein the rounded sidewall of the blocking insulating layer is planarized through a trimming process.

21. The method according to claim 19,
wherein the sidewalls of the plurality of second interlayer insulating layers are convex in relation to the hole,
wherein the exposed area of the blocking insulating layer corresponds to a rounded sidewall facing the hole on the sidewalls of the plurality of second interlayer insulating layers, and
wherein the tunnel insulating layer extends to cover the rounded side.

22. A method of manufacturing a semiconductor memory device, the method comprising:
alternately stacking a plurality of first interlayer insulating layers and a plurality of sacrificial layers in a first direction;
forming a hole that passes through the plurality of first interlayer insulating layers and the plurality of sacrificial layers;
forming a plurality of second interlayer insulating layers on sidewalls of the plurality of first interlayer insulating layers facing the hole to define an uneven portion on a sidewall of the hole;
forming a sacrificial insulating layer along the uneven portion to cover sidewalls of the plurality of second interlayer insulating layers and sidewalls of the plurality of sacrificial layers and to have a plurality of grooves corresponding to the plurality of sacrificial layers;
forming a plurality of data storage patterns on an inner wall of the sacrificial insulating layer to respectively fill the plurality of grooves of the sacrificial insulating layer;
forming a tunnel insulating layer inside the hole to cover the plurality of data storage patterns and the sacrificial insulating layer;
forming a channel layer along an inner wall of the tunnel insulating layer;
removing the plurality of sacrificial layers to define a plurality of openings that expose the sacrificial insulating layer;
removing an exposed portion of the sacrificial insulating layer so that the plurality of data storage patterns are exposed through the plurality of openings;
selectively depositing a preliminary layer on an exposed surface of each of the plurality of data storage patterns;
forming a blocking insulation pattern by modifying the preliminary layer; and
forming a plurality of conductive layers inside the plurality of openings that are opened by the blocking insulation pattern.

23. The method according to claim 22, wherein forming the plurality of data storage patterns comprises:
forming a data storage layer on the inner wall of the sacrificial insulating layer to fill the plurality of grooves of the sacrificial insulating layer;
removing a portion of the data storage layer with hydrofluoric acid (HF) to reduce a thickness of the data storage layer; and
removing a portion of the data storage layer with phosphoric acid (H₃PO₄) so that the data storage layer with a reduced thickness is separated into the plurality of data storage patterns.

24. The method according to claim 22,
wherein the sidewalls of the plurality of second interlayer insulating layers are convex in relation to the hole,
wherein the sacrificial insulating layer comprises a rounded sidewall facing the hole between the plurality of data storage patterns, and
wherein the tunnel insulating layer extends to cover the rounded side.

25. The method according to claim 22,
wherein the sidewalls of the plurality of second interlayer insulating layers are convex in relation to the hole,
wherein the sacrificial insulating layer comprises a rounded sidewall facing the hole between the plurality of data storage patterns, and
wherein the rounded sidewall of the sacrificial insulating layer or the sidewalls of the plurality of second interlayer insulating layers are planarized through a trimming process.

26. The method according to claim 22, wherein the blocking insulation pattern has a lower dielectric constant than a silicon dioxide layer.

27. The method according to claim 22, wherein the blocking insulation pattern is thicker than the sacrificial insulation pattern.

28. The method according to claim 22,
wherein the preliminary layer comprises silicon oxycarbide, and
wherein the preliminary layer is modified into the blocking insulation pattern by annealing the silicon oxycarbide.

29. The method according to claim 22,
wherein the preliminary layer comprises the same material as the plurality of data storage patterns, and
wherein the preliminary layer is modified into the blocking insulation pattern by oxidizing the preliminary layer.
